(19) United States
(12) Patent Application Publication
(10) Pub. No.: US 2025/0210591 A1
(43) Pub. Date: Jun. 26, 2025

(54) APPARATUS, SYSTEM, AND METHOD FOR BALANCING TIMING CLOSURE

(71) Applicant: Advanced Micro Devices, Inc., Santa Clara, CA (US)

(72) Inventors: Russell Schreiber, Austin, TX (US); Stephen Dussinger, Ft. Collins, CO (US); Eric Busta, Ft. Collins, CO (US); Ryan J. Miller, Ft. Collins, CO (US); John Wuu, Ft. Collins, CO (US)

(73) Assignee: Advanced Micro Devices, Inc., Santa Clara, CA (US)

(21) Appl. No.: 18/395,212

(22) Filed: Dec. 22, 2023

(51) Int. Cl. H01L 25/065; H01L 25/00; H03K 5/00; H03K 5/01

(52) U.S. Cl. CPC H01L 25/0657; H01L 25/50; H01L 2225/06541; H03K 2005/00019; H03K 5/01

(57) ABSTRACT

An integrated circuit die includes a set of electronic circuits disposed on a semiconductor material. The integrated circuit die also includes one or more through-silicon vias that vertically span the semiconductor material to transmit data signals. Additionally, the integrated circuit die includes a programmable delay element integrated with the set of electronic circuits on the semiconductor material and configured to delay data signals. Various other apparatuses, systems, and methods are also disclosed.

### BACKGROUND

In computing systems, electrical circuits can be designed on separate components, such as a die or a chip, and combined to create more complex systems. Integrated circuits can be customized and designed to perform specific functions, and multiple components can be modularly combined to increase performance. In some computing systems, similar components can be combined as an interconnected stack, with the combination acting as a single device. For example, dies can be stacked together to create a three-dimensional integrated circuit that reduces the overall footprint of the components and power consumption while increasing computing power or memory.

### BRIEF DESCRIPTION OF THE DRAWINGS

The accompanying drawings illustrate a number of example implementations and are a part of the specification. Together with the following description, these drawings demonstrate and explain various principles of the present disclosure.

FIG. 1 illustrates a side view of an example three-dimensional integrated circuit with exemplary programmable delay elements integrated with each die.

FIG. 2 illustrates a circuit diagram of an example timing closure problem for an exemplary base die broadcasting data to an exemplary die stack.

FIG. 3 illustrates a circuit diagram of exemplary programmable delay elements that implement delays for an exemplary base die broadcasting data to an exemplary die stack.

FIG. 4 illustrates a circuit diagram of an example timing closure problem for an exemplary base die receiving data from an exemplary die stack.

FIG. 5 illustrates a circuit diagram of exemplary programmable delay elements that implement delays for an exemplary base die receiving data from an exemplary die stack.

FIG. 6 is a flow diagram of an example method of manufacturing for integrating programmable delay elements into integrated circuit dies.

FIG. 7 is a block diagram illustrating an example testing and adjustment of timing during the manufacturing of an exemplary programmable delay element.

Throughout the drawings, identical reference characters and descriptions indicate similar, but not necessarily identical, elements. While the example implementations described herein are susceptible to various modifications and alternative forms, specific implementations have been shown by way of example in the drawings and will be described in detail herein. However, the example implementations described herein are not intended to be limited to the particular forms disclosed. Rather, the present disclosure covers all modifications, equivalents, and alternatives falling within the scope of the appended claims.

### DETAILED DESCRIPTION OF EXAMPLE IMPLEMENTATIONS

The present disclosure is generally directed to apparatuses, systems, and methods for balancing timing closure, particularly for three-dimensional integrated circuits. As described below, by vertically stacking integrated circuits or dies, a computing system can maintain a smaller circuit footprint and reduce power consumption in comparison to many two-dimensional configurations. For example, a three-dimensional integrated circuit of multiple, identical stacked die can replace a horizontal die configuration of a much larger footprint. In this example, the vertically stacked dies can be electronically interconnected, such as by through-silicon vias (TSVs) integrated into each die. To send data through the stack, the TSVs can transmit data to each layer of dies.

However, each die within a stack can have different timing paths, offset positions, different fuses, or other variations regardless of whether the dies are intended to be identical. In other words, because the dies are not a single piece of silicon, inconsistencies in manufacturing and placement can create global variations between dies. For example, different dies can have different global transistor variations, different metal properties due to mask shifts, and/or other processing differences. These variations can then lead to increased problems with timing closure in comparison to two-dimensional configurations. For example, two cached macros that are linearly arranged on the same die can have less timing variation than macros on two different stacked dies. Additionally, the placement of each die can increase variations as dies are stacked higher. Specifically, the die nearest to a base die can have a problem with hold slack, while the furthest die can have a problem with setup slack. Without configurable designs, timing closure can become difficult to achieve.

In some examples, an asynchronous interface can be used to ensure closure of both setup timing and hold timing. However, this can impose a heavy latency penalty. Alternatively, by making the entire chip-to-chip path multicycle, this design can impose a heavy bandwidth penalty. In other examples, by actively skewing a clock with a loop, such as a delay-locked loop, the design can impose a heavy power penalty. In contrast, hard coding delays into each die can result in a need for a large variety of dies with different delays based on configuration and placement, making die manufacturing expensive and binning difficult. Thus, a more flexible and efficient design for delays is needed to ensure timing closure on stacked dies.

In some implementations, the disclosed integrated circuit die includes connections, such as TSVs, to interface with other dies in a stack. In these implementations, the TSVs can transmit data signals between dies. In a non-limiting example, the disclosed integrated circuit die can include a programmable delay element configured to delay data signals. By integrating the programmable delay element into the integrated circuit, the disclosed die can control a timing of incoming and outgoing data signals to ensure timing closure. In some non-limiting examples, a programmable delay element can be independently integrated into each die within a stack. In other examples, programmable delay elements can be independently controlled via fuses to delay the timing of data signals, thereby enabling setup and hold timing to be closed on each die while maximizing overall frequency.

Furthermore, a computing system can include a three-dimensional integrated circuit. In some implementations, the three-dimensional integrated circuit can include multiple, identical dies, each with a programmable delay element to control the timing of data signals for the die. By integrating independently programmable delay elements, each die can be uniquely programmed to simultaneously close setup and hold timing at high speeds. Additionally, by enabling the tuning of the delay of each die post-silicon, the three-dimensional integrated circuit can avoid timing discrepancies due to manufacturing inconsistencies. In other words, the programmable delay element enables each layer in a die stack to be identically designed while also enabling different delay settings on each die via a fuse. Thus, the disclosed apparatus, system, and method of manufacturing integrate programmable delay elements into integrated circuit dies for better timing closure.

As will be described in greater detail below, the present disclosure describes various apparatuses, systems, and methods for balancing timing closure. In one implementation, an integrated circuit die includes a set of electronic circuits disposed on a semiconductor material. The integrated circuit die also includes one or more through-silicon vias (TSVs) that vertically span the semiconductor material to transmit data signals. Additionally, the integrated circuit die includes a programmable delay element integrated with the set of electronic circuits on the semiconductor material and configured to delay data signals.

In one example, the programmable delay element is configured to delay an incoming data signal arriving at the integrated circuit die to enable a closure of a setup timing of the incoming data signal and/or a hold timing of the incoming data signal. In this example, the programmable delay element is configured to enable the closure of the setup timing of the incoming data signal by implementing a low delay. Additionally or alternatively, in this example, the programmable delay element is configured to enable the closure of the hold timing of the incoming data signal by implementing a high delay.

In one example, the programmable delay element is configured to delay an outgoing data signal from the integrated circuit die to enable a closure of a setup timing of the outgoing data signal and/or a hold timing of the outgoing data signal. In this example, the programmable delay element is configured to enable the closure of the setup timing of the outgoing data signal by implementing a low delay. Additionally or alternatively, in this example, the programmable delay element is configured to enable the closure of the hold timing of the outgoing data signal by implementing a high delay.

In one example, the programmable delay element further includes one or more fuses electronically coupled to the programmable delay element and configured to control the programmable delay element within a three-dimensional integrated circuit, wherein the integrated circuit die is stacked with one or more other integrated circuit dies.

In one implementation, a three-dimensional integrated circuit includes a base die. The three-dimensional integrated circuit also includes a stack of two or more dies electronically coupled to an interface of the base die, wherein a programmable delay element is integrated with each die to control a timing of a data signal and one or more TSVs vertically span each die to interconnect to other dies to transmit data signals.

In one example, the two or more dies are identically designed. In this example, the two or more dies are vertically stacked by electronically coupling an interface of a first die with an interface of a second die such that one or more TSVs of the first die is aligned to one or more TSVs of the second die. In this example, the stack of the two or more dies is electronically coupled to the interface of the base die by electronically coupling the interface of the first die with the interface of the base die such that the one or more TSVs of the first die is aligned to an electronic component of the base die.

In one example, the base die is configured to broadcast data to each die of the stack, wherein the base die broadcasts data to a distal die through one or more TSVs of a proximal die. In this example, the base die is configured to receive data from each die of the stack, wherein the base die receives data from the distal die through the one or more TSVs of the proximal die.

In one example, the programmable delay element is configured to independently control the timing of the data signal for a single die within the stack.

In one example, the programmable delay element is configured to set a configuration bit to change a delay of the data signal based on a position of a die within the stack and/or a clock skew between the die within the stack and one or more other dies. In this example, the programmable delay element is configured to implement a low delay to close a setup timing of the data signal for a die within the stack distal to the base die. Additionally, in this example, the programmable delay element is configured to implement a high delay to close a hold timing of the data signal for a die within the stack proximal to the base die.

In one implementation, a method of manufacturing includes disposing a set of electronic circuits on a semiconductor material of an integrated circuit. The method of manufacturing also includes forming one or more TSVs to vertically span the semiconductor material, wherein the one or more TSVs are configured to transmit data signals. The method of manufacturing then includes integrating a programmable delay element with the set of electronic circuits, wherein the programmable delay element is configured to delay data signals.

In one example, the method of manufacturing further includes performing a pre-silicon validation of the integrated circuit by calculating a clock skew of the integrated circuit based on a position of the integrated circuit within a stack of dies and setting a configuration bit of the programmable delay element. In this example, the method of manufacturing further includes performing a post-silicon validation of the integrated circuit by stacking the integrated circuit in the stack of dies, testing a timing of the integrated circuit within the stack of dies, and reprogramming the configuration bit of the programmable delay element based on the testing.

Features from any of the implementations described herein can be used in combination with one another in accordance with the general principles described herein. These and other implementations, features, and advantages will be more fully understood upon reading the following detailed description in conjunction with the accompanying drawings and claims.

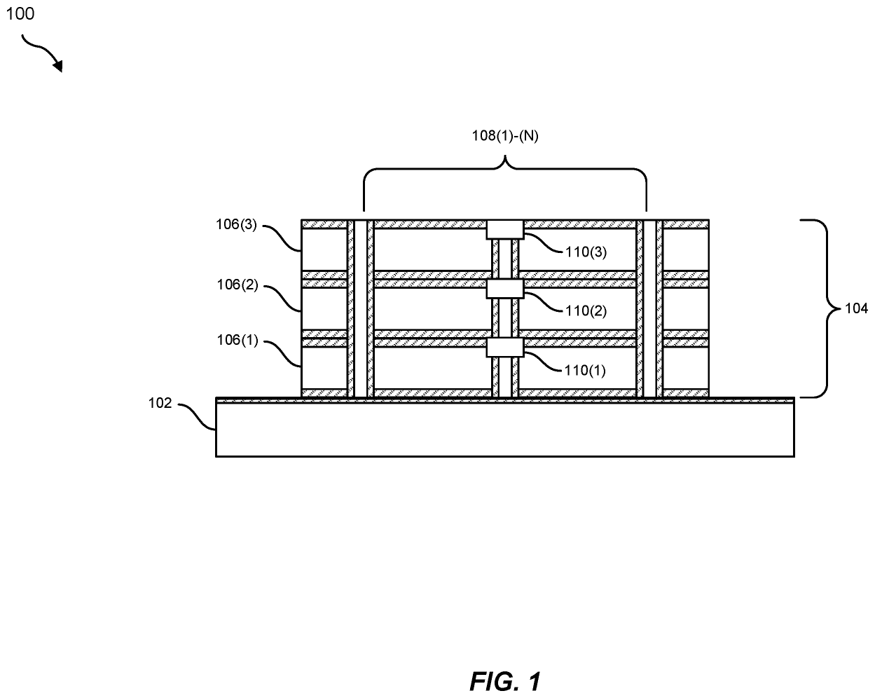

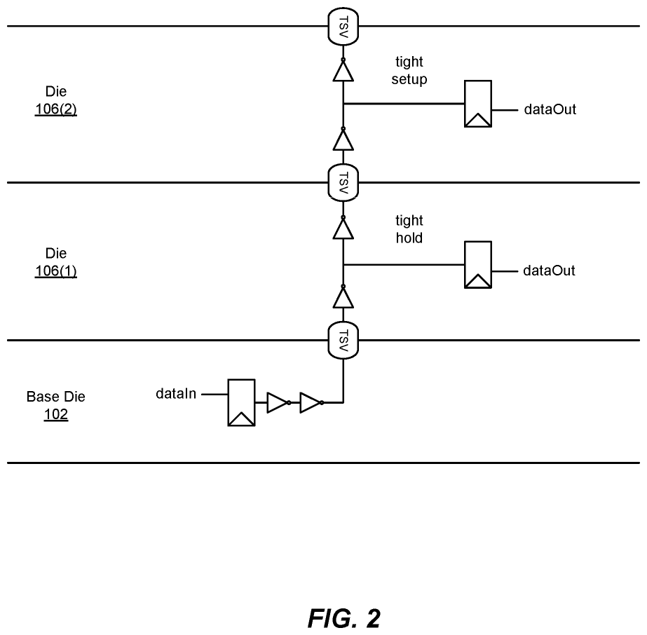

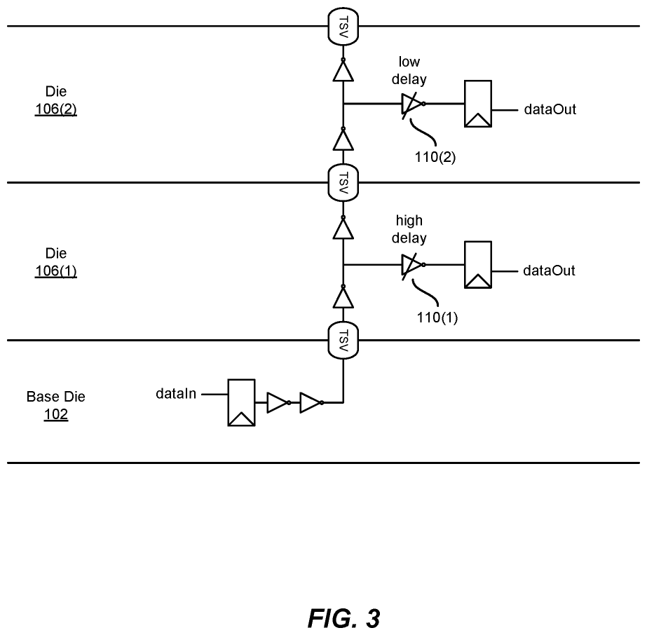

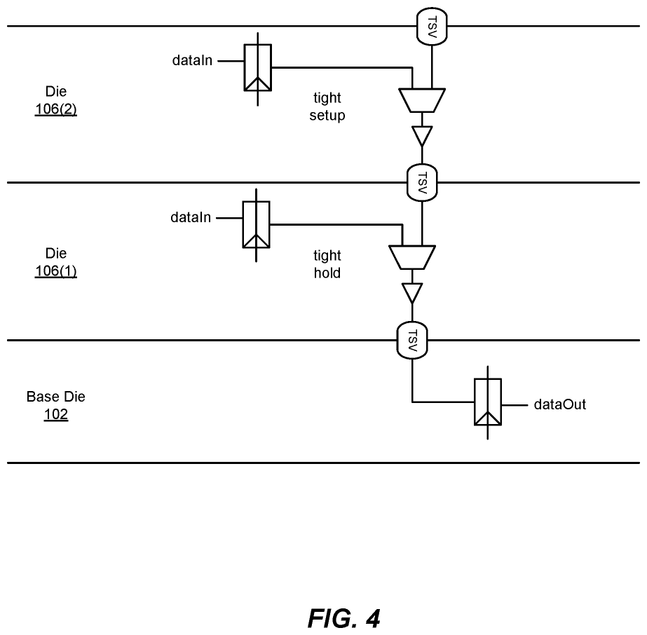

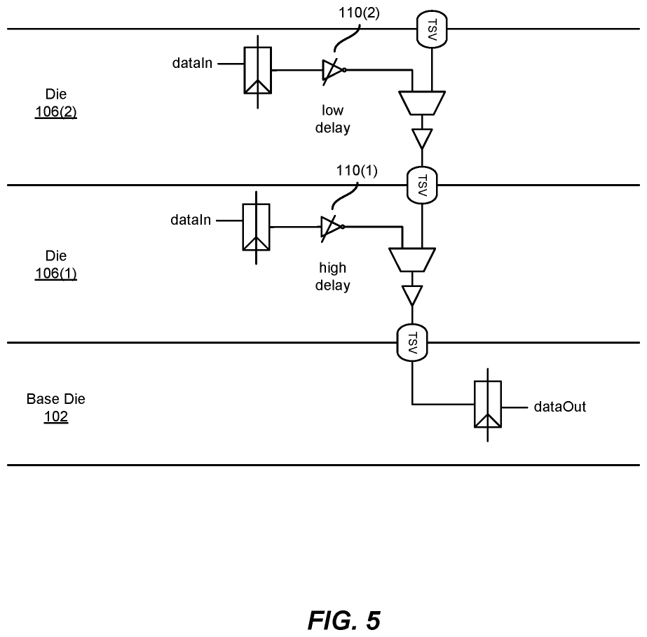

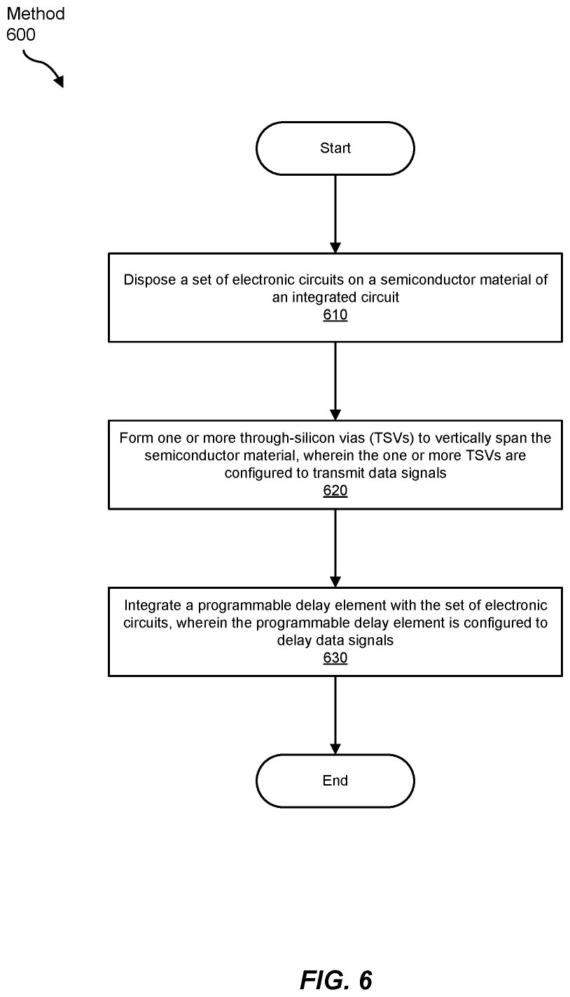

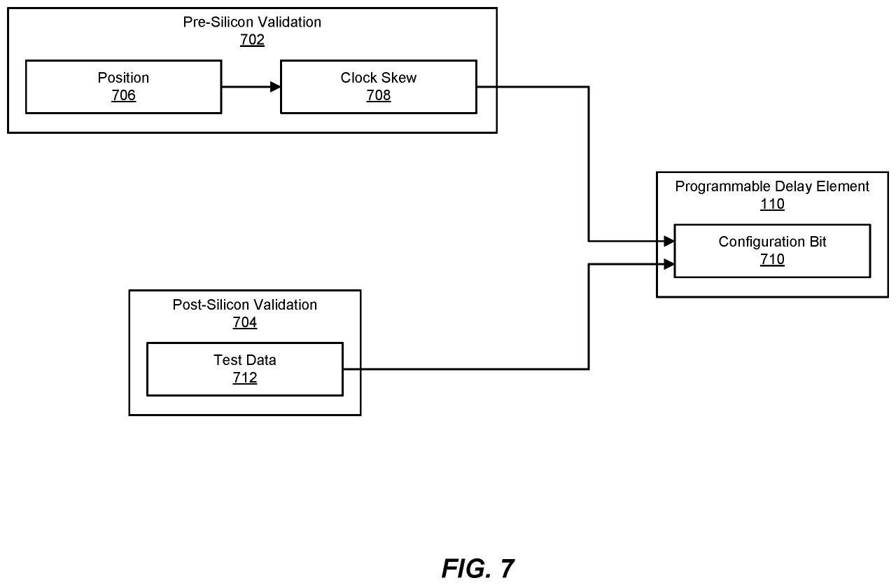

The following will provide, with reference to FIG. 1, detailed descriptions of example three-dimensional integrated circuits with exemplary programmable delay elements integrated with each die. Detailed descriptions of example timing closure problems will be provided in connection with FIG. 2 and FIG. 4. In addition, detailed descriptions of exemplary programmable delay elements that implement delays for integrated circuit dies will be provided in connection with FIG. 3 and FIG. 5. Furthermore, detailed descriptions of exemplary methods of manufacturing integrated circuit dies with programmable delay elements will be provided in connection with FIG. 6. Detailed descriptions of example testing and adjustment of timing during the manufacturing of integrated circuit dies will also be provided in connection with FIG. 7.

FIG. 1 illustrates a side view of an example three-dimensional integrated circuit 100 with exemplary programmable delay elements 110(1)-(3) integrated with dies 106(1)-(3). In non-limiting examples, the terms “die” and “chip” refer to a modular block containing an integrated circuit. In these examples, the term “integrated circuit” refers to an electronic circuit directly integrated and/or etched into an electronic component. Example of dies or chips include, without limitation, system-on-chips (SOCs), graphic processing units (GPUs), central processing units (CPUs), high-bandwidth memory (HBM) stacks, interface circuits, Serializer/Deserializer (SerDes) blocks, semiconductor chips, and/or any other suitable modular components with integrated circuits. In non-limiting examples, the term “three-dimensional integrated circuit” refers to a computing component that includes vertically stacked integrated circuits, such as vertically stacked dies.

In the example of FIG. 1, an integrated circuit die, such as dies 106(1)-(3), includes a set of electronic circuits disposed on a semiconductor material, such as silicon. In this example, each of dies 106(1)-(3) also includes one or more through-silicon vias (TSVs) 108(1)-(N) that vertically span the semiconductor material to transmit data signals. Additionally, each of dies 106(1)-(3) includes programmable delay elements 110(1)-(3), respectively, integrated with the set of electronic circuits on the semiconductor material and configured to delay data signals. Although not illustrated in FIG. 1, in some examples, any or all of programmable delay elements 110(1)-(3) further include one or more fuses electronically coupled to programmable delay elements 110(1)-(3) and configured to control programmable delay elements 110(1)-(3).

In the example of FIG. 1, three-dimensional integrated circuit 100 includes a base die 102. In some examples, base die 102 can also include a semiconductor material. In some examples, base die 102 and dies 106(1)-(3) comprise a rigid material holding a specific form. In some examples, the semiconductor material includes one or more portions acting as an insulator and one or more portions acting as a conductor. In the example of FIG. 1, three-dimensional integrated circuit 100 also includes a stack 104 of dies 106(1)-(3) electronically coupled to an interface of the base die, wherein programmable delay elements 110(1)-(3) are integrated with dies 106(1)-(3) to control a timing of a data signal, and TSVs 108(1)-(N) vertically span dies 106(1)-(3) to interconnect to each other and base die 102 to transmit data signals.

In some examples, three-dimensional integrated circuit 100 can be all or a portion of a computing system that generally represents any type or form of computing system or computing device with electronic components to perform computing functions. Examples of computing systems include, without limitation, chiplets, printed circuit boards (PCBs), processors, and/or other electronic components or combinations of the same. Additional examples of computing systems include, without limitation, laptops, tablets, desktops, servers, cellular phones, Personal Digital Assistants (PDAs), multimedia players, embedded systems, wearable devices (e.g., smart watches, smart glasses, etc.), smart vehicles, so-called Internet-of-Things devices (e.g., smart appliances, etc.), gaming consoles, servers, variations or combinations of one or more of the same, a portion of one or more of the same, or any other suitable computing device.

Many other devices or subsystems can be connected to three-dimensional integrated circuit 100 in FIG. 1 or similar computing systems. Conversely, the components and devices illustrated in FIG. 1 need not be present to practice the implementations described and/or illustrated herein. The devices and subsystems referenced above can also be interconnected in different ways from that shown in FIG. 1. Three-dimensional integrated circuit 100 or related computing systems can also employ any number of software, firmware, and/or hardware configurations. For example, three-dimensional integrated circuit 100 can include additional dies, additional stacks, and/or any other suitable computing components to carry out one or more of the functions described herein.

In one example, dies 106(1)-(3) are identically designed. In this example, dies 106(1)-(3) are vertically stacked by electronically coupling an interface of die 106(1) with an interface of die 106(2) such that one or more of TSVs 108(1)-(N) of die 106(1) is aligned to one or more of TSVs 108(1)-(N) of die 106(2). Similarly, an interface of die 106(2) is electronically coupled to an interface of die 106(3) such that one or more of TSVs 108(1)-(N) of die 106(2) is aligned to one or more of TSVs 108(1)-(N) of die 106(3). In the example of FIG. 1, a bottom interface of die 106(2) is coupled to a top interface of die 106(1), and a bottom interface of die 106(3) is coupled to a top interface of die 106(2). Additionally, stack 104 is electronically coupled to the interface of base die 102 by electronically coupling a bottom interface of die 106(1) with the interface of base die 102 such that one or more of TSVs 108(1)-(N) of die 106(1) is aligned to an electronic component of base die 102. In other examples, dies 106(1)-(3) can include variations between dies and/or different components.

In one example, base die 102 is configured to broadcast data to dies 106(1)-(3) of stack 104, wherein base die 102 broadcasts data to die 106(2) through one or more of TSVs 108(1)-(N) of die 106(1). In this example, base die 102 broadcasts data to die 106(3) through one or more of TSVs 108(1)-(N) of both die 106(1) and die 106(2). Similarly, in some examples, base die 102 is configured to receive data from dies 106(1)-(3) of stack 104, wherein base die 102 receives data from die 106(2) through one or more of TSVs 108(1)-(N) of die 106(1) and data from die 106(3) through one or more of TSVs 108(1)-(N) of both die 106(1) and die 106(2).

In one example, programmable delay elements 110(1)-(3) are configured to independently control the timing of the data signal for each of dies 106(1)-(3) within stack 104. For example, programmable delay element 110(1) is configured to control the timing of the data signal for die 106(1) independently of dies 106(2)-(3), which are controlled by programmable delay elements 110(2)-(3).

FIG. 2 illustrates a circuit diagram of an example timing closure problem for base die 102 broadcasting data to stack 104 comprising die 106(1) and die 106(2). In non-limiting examples, the term “timing closure” refers to a process to ensure signals arrive within an expected window for a die or chip. In these examples, a setup slack refers to a difference between the required time and the arrival time of data, and a hold slack refers to a difference between the arrival time and the required time of data. In these examples, positive slack indicates a chip is performing within parameters, and negative slack indicates a chip does not meet timing constraints, which may result in a failed chip. In these examples, a setup path launches from one clock rise edge and must reach a destination by the next clock rise edge. For example, a setup-challenged path occurs when a clock signal arrives before the data. In contrast, a hold-challenged path occurs when a clock skew causes the data to arrive before the clock signal, which is not resolvable by slowing down the clock and can be fatal to the chip. In other words, setup time is clock-cycle correctable by slowing down the clock while hold time is not.

In the example of FIG. 2, an incoming data signal arriving at die 106(1) can result in a tight hold, with die 106(1) having a problem closing timing for a particular hold path. In contrast, an incoming data signal arriving at die 106(2) can result in a tight setup, with die 106(2) having a problem closing timing for a particular setup path. In other words, when broadcasting data from base die 102 to multiple, identical stacked dies 106(1)-(2), the nearer proximal die is likely to have a challenge closing hold time while the farther distal die is likely to have a challenge closing setup time. Whether a die has a challenging setup or hold timing window from a flop on one die to a flop on another die can depend on where the die is in stack 104.

FIG. 3 illustrates a circuit diagram of exemplary programmable delay elements 110(1)-(3) that implement delays for base die 102 broadcasting data to stack 104. In the example of FIG. 3, programmable delay element 110(1) is configured to delay the incoming data signal arriving at die 106(1) to enable a closure of a hold timing of the incoming data signal. In this example, programmable delay element 110(1) is configured to enable the closure of the hold timing of the incoming data signal by implementing a high delay.

Similarly, in the example of FIG. 3, programmable delay element 110(2) is configured to delay the incoming data signal arriving at die 106(2) to enable a closure of a setup timing of the incoming data signal. In this example, programmable delay element 110(2) is configured to enable the closure of the setup timing of the incoming data signal by implementing a low delay.

In one example, programmable delay element 110(1) and/or programmable delay element 110(2) can be configured to set a configuration bit to change a delay of the data signal based on a position of die 106(1) and/or die 106(2) within stack 104. Additionally or alternatively, the configuration bit can be set based on a clock skew between base die 102 and die 106(1) and/or a clock skew between die 106(1) and die 106(2). The clock skew is calculated as a difference between the arrival times of incoming clock signals at each die, which can be caused by different path lengths to arrive at the clock pin of the flip-flops of each die. The amount of delay set for each die can be calculated based on the clock skew between the dies. Due to dies 106(1)-(2) being separate components with potential differences in the silicon material, clock skew can be greater than the clock skew across a single die or chip. In some examples, dies 106(1)-(2) can represent dies of different types of technology or materials, rather than simply global variations.

In some examples, programmable delay element 110(1) can be configured to implement a high delay to close a hold timing of the data signal for die 106(1) due to its proximal position to base die 102. Similarly, programmable delay element 110(2) can be configured to implement a low delay to close a setup timing of the data signal for die 106(2) due to its distal position to base die 102. Thus, programmable delay element 110(1) is set at the high delay for a tight hold path, and programmable delay element 110(2) is set at the low delay for a tight setup path.

FIG. 4 illustrates a circuit diagram of an example timing closure problem for base die 102 receiving data from dies 106(1)-(2) of stack 104. Similar to broadcasting data from base die 102, receiving data from die 106(2) is likely to have a challenging setup path while receiving data from die 106(1) is likely to have a challenging hold path. In other words, base die 102 receiving data from die 106(2) is likely to take longer than receiving data from die 106(1) due to the farther path from die 106(2) to base die 102. Thus, die 106(1) has a tight hold again for outgoing data, and die 106(2) has a tight setup again for outgoing data.

FIG. 5 illustrates a circuit diagram of exemplary programmable delay elements 110(1)-(2) that implement delays for base die 102 receiving data from dies 106(1)-(2). In the example of FIG. 5, programmable delay element 110(1) is configured to delay an outgoing data signal from die 106(1) to enable a closure of a hold timing of the outgoing data signal. In this example, programmable delay element 110(1) is configured to enable the closure of the hold timing of the outgoing data signal by implementing a high delay. Similarly, programmable delay element 110(2) is configured to delay an outgoing data signal from die 106(2) to enable a closure of a setup timing of the outgoing data signal. In this example, programmable delay element 110(2) is configured to enable the closure of the setup timing of the outgoing data signal by implementing a low delay. In other words, programmable delay element 110(1) is set at the high delay for a tight hold path, and programmable delay element 110(2) is set at the low delay for a tight setup path. Similar to FIG. 3, programmable delay elements 110(1)-(2) set a configuration bit to change a delay of the outgoing data signal based on the position of dies 106(1)-(2) and/or the clock skew between dies.

FIG. 6 shows an example method for manufacturing, assembling, using, adjusting, or otherwise configuring or creating the systems and apparatuses presented herein. The steps shown in FIG. 6 can be performed by any individual and/or by any suitable type or form of manual and/or automated apparatus. In particular, FIG. 6 illustrates a flow diagram of an exemplary method 600 for integrating programmable delay elements into integrated circuit dies.

As shown in FIG. 6, at step 610, one or more of the systems described herein can dispose a set of electronic circuits on a semiconductor material of an integrated circuit. For example, as illustrated in FIG. 1, dies 106(1)-(3) include electronic circuits constructed on silicon material that interface with other dies.

The systems described herein can perform step 610 in a variety of ways. As shown in FIG. 1, sets of electronic circuits on die 106(1) can represent a bottom interface that electronically couples to base die 102 and/or a top interface that electronically couples to die 106(2). Similarly, dies 106(2)-(3) can include both a bottom interface and a top interface. Although not coupled to another electronic component, the top interface of die 106(3) can be modified to couple to additional dies or stacks or to close a circuit.

Returning to FIG. 6, at step 620, one or more of the systems described herein can form one or more TSVs to vertically span the semiconductor material, wherein the one or more TSVs are configured to transmit data signals. For example, as illustrated in FIG. 1, TSVs 108(1)-(N) are formed to vertically span the semiconductor material of dies 106(1)-(3) to transmit data signals to dies 106(1)-(3).

The systems described herein can perform step 620 of FIG. 6 in a variety of ways. In some examples, TSVs 108(1)-(N) can be embedded in dies 106(1)-(3) such that a TSV conducts an electrical charge to transmit data signals. For example, TSVs 108(1)-(N) can include a conductive material, such as copper, to more easily transmit electricity. In one example, any or all of TSVs 108(1)-(N) can be formed prior to constructing the set of electronic circuits on the semiconductor material. In other examples, any or all of TSVs 108(1)-(N) can be formed after completing the set of electronic circuits. Additionally, the placement of TSVs 108(1)-(N) can be designed as part of the circuitry of dies 106(1)-(3).

Returning to FIG. 6, at step 630, one or more of the systems described herein can integrate a programmable delay element with the set of electronic circuits, wherein the programmable delay element is configured to delay data signals. For example, as illustrated in FIG. 1, programmable delay elements 110(1)-(3) are integrated into dies 106(1)-(3) to delay data signals to and from dies 106(1)-(3).

The systems described herein can perform step 630 of FIG. 6 in a variety of ways. In some examples, programmable delay elements 110(1)-(3) can be controlled by one or more fuses disposed on dies 106(1)-(3). Additionally, programmable delay elements 110(1)-(3) can set a configuration bit to change a delay of incoming and/or outgoing data signals.

In one example, the method of manufacturing can further include performing a pre-silicon validation of the integrated circuit by calculating a clock skew of the integrated circuit based on a position of the integrated circuit within a stack of dies. In this example, the method of manufacturing can set the configuration bit of the programmable delay element. Additionally, the method of manufacturing can further include performing a post-silicon validation of the integrated circuit by stacking the integrated circuit in the stack of dies, testing the timing of the integrated circuit within the stack of dies, and reprogramming the configuration bit of the programmable delay element based on the result. In non-limiting examples, the term “pre-silicon validation” refers to a process of verifying that the design of a chip or a die meets specifications prior to manufacturing. For example, a pre-silicon timing report can be generated using simulations of a computing component to determine if slack and hold timing meet chip requirements. In non-limiting examples, the term “post-silicon validation” refers to a process of verifying that the functionality of a chip or a die meets specifications after manufacturing.

FIG. 7 shows a block diagram illustrating an example testing and adjustment of timing during the manufacturing of an exemplary programmable delay element 110. As shown in FIG. 7, a pre-silicon validation 702 can include simulating a clock skew 708 of the integrated circuit based on a position 706 of the integrated circuit within a stack of dies. In this example, pre-silicon validation 702 can include setting a configuration bit 710 of programmable delay element 110 based on clock skew 708. For example, clock skew 708 of die 106(1) of FIG. 3 can be lower than a clock skew of die 106(2) due to the proximal position of die 106(1) to base die 102. In this example, pre-silicon validation 702 can set configuration bit 710 to a higher delay for die 106(1) in comparison to die 106(2). In this example, dies 106(1)-(2) can be manufactured with different delays. In other words, rather than adding another buffer in a macro, the disclosed method can publish the macro and set configuration bit 710 to adjust for clock skew 708. Pre-silicon validation 702 can perform static timing analysis to determine whether a stack of dies can simultaneously pass setup timing and hold timing.

Subsequently, the method of manufacturing disclosed herein can perform a post-silicon validation 704 of FIG. 7 to stack dies 106(1)-(2) together and on top of base die 102. This method can then generate test data 712 for die 106(1) and reprogram configuration bit 710 to fine tune the timing differences between die 106(1) and die 106(2). For example, test data 712 can identify the setup slack and hold slack of dies 106(1)-(2). In this example, test data 712 can identify programmable delay settings that maximize a frequency of a die, for setup paths, while ensuring the die meets a hold timing and is, thus, functional. The delays of dies 106(1)-(2) can be more easily tuned post-silicon using configuration bit 710. A larger stack of dies can include a wider range of delays to synchronize closer and farther dies. With both pre-silicon validation and post-silicon validation, the disclosed method includes more opportunities to close timing with more granular control.

In some examples, the disclosed method can stack dies 106(1)-(3) of FIG. 1 by bonding dies 106(1)-(3) in stack 104 to each other and bonding stack 104 to base die 102 using die bonding. In some examples, the term “die bonding” refers to a method of attaching a die to a substrate or to another die. Examples of die bonding include, without limitation, direct bonding, hybrid bonding, copper-to-copper bonding, surface activated bonding, adhesive bonding, variations or combinations of one or more of the same, and/or any other suitable method for attaching dies. In these examples, the disclosed method can stack and bond dies 106(1)-(3) by matching the placement of TSVs 108(1)-(N) to ensure TSVs 108(1)-(N) can transmit data signals between dies.

In some examples, the disclosed method can include blowing fuses differently for different components, with some components having one set of fuses with a set delay and other components having a different set of fuses with a different delay. In additional examples, the pre-silicon validation and the post-silicon validation can improve the binning process to categorize each die and ensure the die is within parameters for a particular stack or computing component. In further examples, the disclosed apparatuses and systems can be used for two-dimensional configurations, other three-dimensional technologies like hybrid bonded memory, other data broadcast or data transmission technologies like bus communication, and/or any other suitable computing systems. Furthermore, although described as a data-based delay system, the disclosed systems and apparatuses can be implemented using clocking-based delay systems, wherein clocks are delayed to macros.

As described above, the disclosed apparatuses, systems, and methods balance timing closure of integrated circuit dies to ensure closure of both setup and hold timing for a three-dimensional die stack. Accordingly, the implementations and systems described herein incorporate a programmable delay element into each stacked die to uniquely control a delay of data transmission for each die in the stack. The programmable delay element enables quick what-if analyses when running timing tests prior to manufacturing. For example, the programmable delay element enables faster iterations of pre-silicon simulations to generate timing reports. The disclosed programmable delay element also includes a configuration bit that can be used to adjust the delay after manufacturing is complete, thereby enabling adjustment of the delay based on a position of the die after being stacked. In other words, the programmable delay enables testing of a chip design by setting the configuration bit that changes the delay to optimize the chip. Rather than estimating the appropriate delays for dies, the disclosed methods enable independently programmable delays to be uniquely determined for each die layer to simultaneously close setup and hold timing at high speeds. Thus, the disclosed three-dimensional integrated circuit and the integrated circuit die can provide flexibility and speed while improving timing closure.

While the foregoing disclosure sets forth various implementations using specific block diagrams, flowcharts, and examples, each block diagram component, flowchart step, operation, and/or component described and/or illustrated herein can be implemented, individually and/or collectively, using a wide range of hardware, software, or firmware (or any combination thereof) configurations. In addition, any disclosure of components contained within other components should be considered example in nature since many other architectures can be implemented to achieve the same functionality.

In some examples, all or a portion of exemplary three-dimensional integrated circuit 100 in FIG. 1 can represent portions of a cloud-computing or network-based environment. Cloud-computing environments can provide various services and applications via the Internet. These cloud-based services (e.g., software as a service, platform as a service, infrastructure as a service, etc.) can be accessible through a web browser or other remote interface. Various functions described herein can be provided through a remote desktop environment or any other cloud-based computing environment.

In some examples, all or a portion of exemplary three-dimensional integrated circuit 100 in FIG. 1 can represent portions of a mobile computing environment. Mobile computing environments can be implemented by a wide range of mobile computing devices, including mobile phones, tablet computers, e-book readers, personal digital assistants, wearable computing devices (e.g., computing devices with a head-mounted display, smartwatches, etc.), variations or combinations of one or more of the same, or any other suitable mobile computing devices. In some examples, mobile computing environments can have one or more distinct features, including, for example, reliance on battery power, presenting only one foreground application at any given time, remote management features, touchscreen features, location and movement data (e.g., provided by Global Positioning Systems, gyroscopes, accelerometers, etc.), restricted platforms that restrict modifications to system-level configurations and/or that limit the ability of third-party software to inspect the behavior of other applications, controls to restrict the installation of applications (e.g., to only originate from approved application stores), etc. Various functions described herein can be provided for a mobile computing environment and/or can interact with a mobile computing environment.

The process parameters and sequence of steps described and/or illustrated herein are given by way of example only and can be varied as desired. For example, while the steps illustrated and/or described herein can be shown or discussed in a particular order, these steps do not necessarily need to be performed in the order illustrated or discussed. The various example methods described and/or illustrated herein can also omit one or more of the steps described or illustrated herein or include additional steps in addition to those disclosed.

The preceding description has been provided to enable others skilled in the art to best utilize various aspects of the example implementations disclosed herein. This example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. An integrated circuit die comprising:
a set of electronic circuits disposed on a semiconductor material;
at least one through-silicon via (TSV) that vertically spans the semiconductor material to transmit data signals; and
a programmable delay element integrated with the set of electronic circuits on the semiconductor material and configured to delay data signals.

2. The integrated circuit die of claim 1, wherein the programmable delay element is configured to delay an incoming data signal arriving at the integrated circuit die to enable a closure of at least one of:
a setup timing of the incoming data signal; and
a hold timing of the incoming data signal.

3. The integrated circuit die of claim 2, wherein the programmable delay element is configured to enable the closure of the setup timing of the incoming data signal by implementing a low delay.

4. The integrated circuit die of claim 2, wherein the programmable delay element is configured to enable the closure of the hold timing of the incoming data signal by implementing a high delay.

5. The integrated circuit die of claim 1, wherein the programmable delay element is configured to delay an outgoing data signal from the integrated circuit die to enable a closure of at least one of:
a setup timing of the outgoing data signal; and
a hold timing of the outgoing data signal.

6. The integrated circuit die of claim 5, wherein the programmable delay element is configured to enable the closure of the setup timing of the outgoing data signal by implementing a low delay.

7. The integrated circuit die of claim 5, wherein the programmable delay element is configured to enable the closure of the hold timing of the outgoing data signal by implementing a high delay.

8. The integrated circuit die of claim 1, further comprising at least one fuse electronically coupled to the programmable delay element and configured to control the programmable delay element within a three-dimensional integrated circuit, wherein the integrated circuit die is stacked with at least one other integrated circuit die.

9. A three-dimensional integrated circuit comprising:
a base die; and
a stack of at least two dies electronically coupled to an interface of the base die, wherein:
a programmable delay element is integrated with each die to control a timing of a data signal; and
at least one through-silicon via (TSV) vertically spans each die to interconnect to other dies to transmit data signals.

10. The three-dimensional integrated circuit of claim 9, wherein the at least two dies are identically designed and vertically stacked by electronically coupling an interface of a first die with an interface of a second die such that at least one TSV of the first die is aligned to at least one TSV of the second die.

11. The three-dimensional integrated circuit of claim 10, wherein the stack of the at least two dies is electronically coupled to the interface of the base die by electronically coupling the interface of the first die with the interface of the base die such that the at least one TSV of the first die is aligned to an electronic component of the base die.

12. The three-dimensional integrated circuit of claim 9, wherein the base die is configured to broadcast data to each die of the stack, wherein the base die broadcasts data to a distal die through at least one TSV of a proximal die.

13. The three-dimensional integrated circuit of claim 12, wherein the base die is configured to receive data from each die of the stack, wherein the base die receives data from the distal die through the at least one TSV of the proximal die.

14. The three-dimensional integrated circuit of claim 9, wherein the programmable delay element is configured to independently control the timing of the data signal for a single die within the stack.

15. The three-dimensional integrated circuit of claim 9, wherein the programmable delay element is configured to set a configuration bit to change a delay of the data signal based on at least one of:
a position of a die within the stack; and
a clock skew between the die within the stack and at least one other die.

16. The three-dimensional integrated circuit of claim 15, wherein the programmable delay element is configured to implement a low delay to close a setup timing of the data signal for a die within the stack distal to the base die.

17. The three-dimensional integrated circuit of claim 15, wherein the programmable delay element is configured to implement a high delay to close a hold timing of the data signal for a die within the stack proximal to the base die.

18. A method of manufacturing comprising:
disposing a set of electronic circuits on a semiconductor material of an integrated circuit;
forming at least one through-silicon via (TSV) to vertically span the semiconductor material, wherein the at least one TSV is configured to transmit data signals; and
integrating a programmable delay element with the set of electronic circuits, wherein the programmable delay element is configured to delay data signals.

19. The method of manufacturing of claim 18, further comprising performing a pre-silicon validation of the integrated circuit by:
calculating a clock skew of the integrated circuit based on a position of the integrated circuit within a stack of dies; and
setting a configuration bit of the programmable delay element.

20. The method of manufacturing of claim 19, further comprising performing a post-silicon validation of the integrated circuit by:
stacking the integrated circuit in the stack of dies;
testing a timing of the integrated circuit within the stack of dies; and
reprogramming the configuration bit of the programmable delay element based on the testing.
